(19) United States
(12) Patent Application Publication
(10) Pub. No.: US 2014/0218050 A1
(43) Pub. Date: Aug. 7, 2014

(54) APPARATUS AND METHOD FOR DETECTING CARD CONNECTION STATUS

(71) Applicant: Nokia Corporation, Espoo (FI)

(72) Inventors: Phillips Lin, Beijing (CN); Steven Liu, Beijing (CN)

(73) Assignee: Nokia Corporation, Espoo (FI)

(21) Appl. No.: 14/137,965

(22) Filed: Dec. 20, 2013

(30) Foreign Application Priority Data
Dec. 31, 2012 (CN) 201210596217.4

(51) Int. Cl. G01R 31/04; H01R 13/703

(52) U.S. Cl. CPC G01R 31/043; H01R 13/703
USPC 324/649; 439/188

(57) ABSTRACT

Embodiments of the present invention relate to apparatus and method for detecting a card connection status. An apparatus for detecting a card connection status is disclosed. The apparatus comprises a switch component operable to change an electric connection status with a contact terminal of a card connector responsive to a change of a connection status between a card and the card connector; a detection circuit operable to generate a detection signal indicating the electric connection status between the switch member and the contact terminal; and a controller operable to determine the connection status between the card and the card connector based on the detection signal from the detection circuit. The corresponding method, detection circuit, and card connector are also disclosed.

### FIELD OF THE INVENTION

Embodiments of the present invention relate to an apparatus and method for detecting card connection status.

### BACKGROUND OF THE INVENTION

Card connectors have been widely used in various fields such as mobile communications and computers. For example, in a general mobile phone, a user usually needs to insert a subscriber identity module (SIM) card to access the functions of the mobile phone. The mobile phone has a card connector for connecting and receiving the card. Generally speaking, the card connector has one or more contact terminals or pins for electrically connecting with corresponding terminals or pins on the card to enable data communication between the card and the hosting terminal is realized. The card connector may also comprise various components for mechanically supporting and/or fixing the card. As known, the connection and/or removal of cards are common in various kinds of other user terminals than mobile phones.

Traditionally the card connector has a dedicated space and processing circuit for detecting connection and removal of the card, which increases the cost of design and manufacturing of the connector. Further, it prevents the reduction of the connector size and therefore is not applicable to the increasingly popular micro-cards or nano-cards. Several solutions have been proposed to solve this problem. For example, in some solutions, a cover member may be utilized to electrically contact the card to detect its connection and removal. However, it can be appreciated that such detection, which relies on the contact between the cover member and the card, suffers from a detection delay. Some other solutions detect the card connection by arranging additional portions, contact terminals, or pads on the card connector. For example, in some prior art arrangement, the card may push an additional spring contact on the connector to ensure that the additional spring contact and one of the card contacts are disconnected. In such solution, the card must be large enough and the circuit complexity is usually high, which is not possible for those small sized cards like nano SIM cards. Also, these solutions usually have to significantly change the structure of the card connector and therefore are incompatible with those existing card connectors.

In view of the foregoing, there is a need in the art for a solution capable of effectively detecting the connection and removal of a card without increasing the mechanical and/or electric complexity of the card and the card connector.

### SUMMARY OF THE INVENTION

In order to address the foregoing and other potential problems, embodiments of the present invention propose an apparatus and method for detecting a card connection status.

In a first aspect, embodiments of the present invention provide an apparatus for detecting a card connection status. The apparatus comprises: a switch component operable to change an electric connection status with a contact terminal of a card connector responsive to a change of a connection status between a card and the card connector; a detection circuit operable to generate a detection signal indicating the electric connection status between the switch member and the contact terminal; and a controller operable to determine the connection status between the card and the card connector based on the detection signal from the detection circuit.

In a second aspect, embodiments of the present invention provide a card connector. The card connector comprises: a housing member; at least one contact terminal; and a switch component operable to change an electric connection status with one of the at least one contact terminal responsive to a change of a connection status between a card and the card connector.

In a third aspect, embodiments of the present invention provide a detection circuit for detecting a card connection status. The detection circuit comprises: a status detection block operable to detect an electrical connection status between a switch member and a contact terminal of a card connector, the electrical connection status changing responsive to a change of a connection status between a card and the card connector; and a detection signal generation block operable to generate a detection signal indicating the electrical connection status between the switch member and the contact terminal for determining the connection status between the card and the card connector.

In a fourth aspect, embodiments of the present invention provide a method for detecting a card connection status. The method comprises: detecting an electrical connection status between a switch member and a contact terminal of a card connector, the electrical connection status changing responsive to a change of a connection status between a card and the card connector; and generating a detection signal indicating the electrical connection status between the switch member and the contact terminal for determining the connection status between the card and the card connector.

These and other optional embodiments of the present invention can be implemented to realize one or more of the following advantages. In accordance with embodiments of the present invention, it is only necessary to equip the card connector with a single simple, small switch member to utilize a contact terminal of the card connector itself to effectively detect the card connection status. Detection of the card connection status may be done with relatively low mechanical and/or electric complexity and therefore is simple and easy to implement. Moreover, embodiments of the present invention may be well compatible with any existing card connectors. In accordance with some optional embodiments, an auxiliary switch member may be involved to realize a pre-warning of the card removal to facilitate hot swap.

### BRIEF DESCRIPTION OF THE DRAWINGS

Through reading the following detailed description with reference to the accompanying drawings, the above and other objectives, features and advantages of the embodiments of the present invention will become more comprehensible. In the drawings, several embodiments of the present invention will be illustrated in an exemplary and non-limiting manner, wherein:

FIG. 1 shows a schematic diagram of a card connector to which exemplary embodiments of the present invention may be applied;

FIG. 2 shows a block diagram of a card connection detecting apparatus in accordance with exemplary embodiments of the present invention;

FIGS. 3A and 3B shows a stereo view and a cross section view of a configuration of a switch member and a card connector in accordance with exemplary embodiments of the present invention;

FIGS. 4A-4B, 5A-5B, and 6A-6B show block diagrams of apparatuses for detecting card connection status in accordance with exemplary embodiments of the present invention;

FIGS. 7A-7C show block diagrams of an auxiliary switch member in disconnected or connected states in accordance with exemplary embodiments of the present invention;

FIGS. 8A-8B and 9A-9B show block diagrams of apparatuses for detecting card connection status with an auxiliary switch member in accordance with the exemplary embodiments of the present invention;

FIG. 10 shows a flowchart of a method for detecting card connection status in accordance with exemplary embodiments of the present invention; and

FIG. 11 shows a block diagram of a user terminal in which exemplary embodiments of the present invention may be implemented.

Throughout the drawings, same or similar reference numbers indicates same or similar elements.

### DETAILED DESCRIPTION OF EMBODIMENTS

Hereinafter, the principle and spirit of the present invention will be described with reference to various exemplary embodiments illustrated in the drawings. It should be appreciated that these embodiments are provided only to enable those skilled in the art to better understand and implement the present invention and should not be constructed as limits of the scope of the invention.

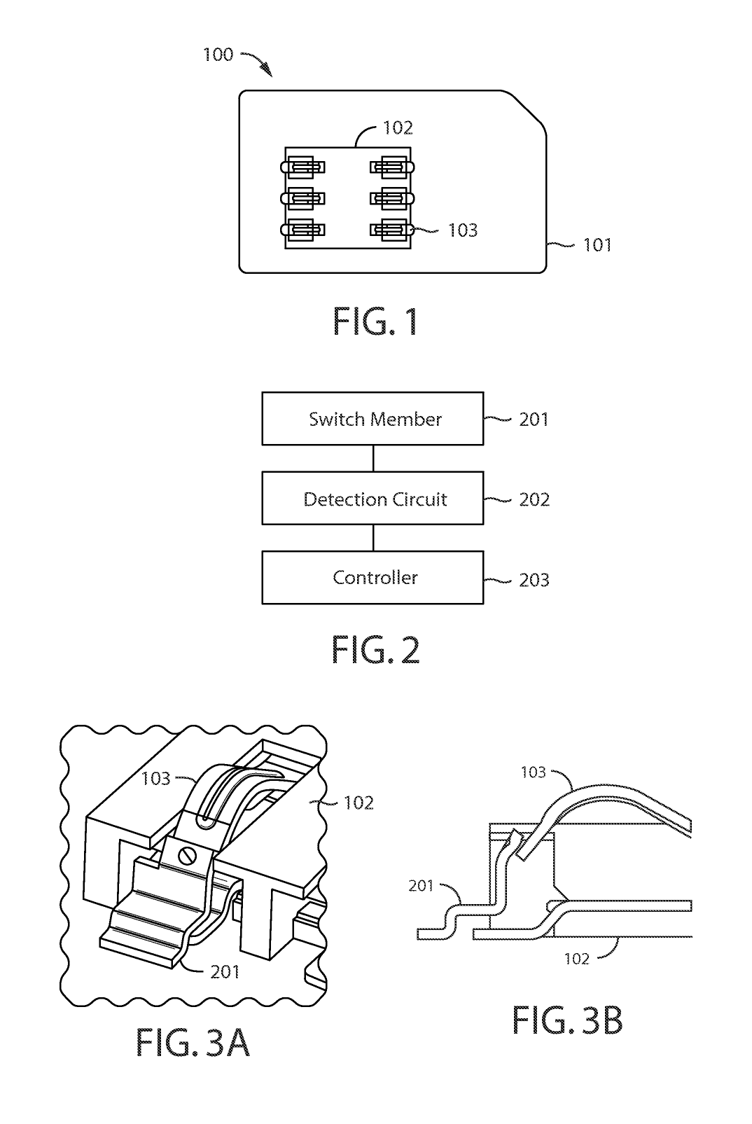

Reference is first made to FIG. 1 where a block diagram of a card connector 100 to which embodiments of the present invention may be applied is shown. The card connector 100 comprises a substrate 101, a housing member 102, and a plurality of contact terminals or pins 103. The housing member 102 is arranged on the substrate 101. The contact terminals 103 are generally made of an elastic conductive material in a form of a spring, for example. In operation, the card may be connected to and fixed by the housing member 102. The contract terminals on the card may contact the plurality of contact terminals 103 on the card connector 100, respectively, to implement an electric connection between the card and the connector for information and data communication.

Now referring to FIG. 2, it shows a block diagram of an apparatus 200 for detecting card connection status in accordance with exemplary embodiments of the present invention. As shown, the apparatus 200 comprises a switch member 201, a detection circuit 202, and a controller 203. In accordance with embodiments of the present invention, the switch member 201 is operable to change an electrical connection status with a contact terminal of the card connector (for example, the contact terminal 103 shown in FIG. 1) responsive to a change of the connection status between the card and the card connector (for example, the card connector 101 shown in FIG. 1). Specifically, if the switch member 201 and the contact terminal 103 are connected with each other when the card and the card connector 100 are connected, then the switch 201 will automatically disconnect from the contact terminal 103 when the card is removed from the card connector 100. On the contrary, if the switch member 201 and the contact terminal 103 are disconnected when the card and the card connector 100 are connected, the switch 201 may automatically connect to the contact terminal 103 when the card is removed from the card connector 100. The structure and principle of operation of the apparatus 200 and its components will be detailed below.

As shown in FIG. 2, the detection circuit 202 is coupled to the switch member 201 and is operable to generate a detection signal indicating the electrical connection status between the switch member 201 and the contact terminal 103 of the card connector. The detection signal generated by the detection circuit 202 may be passed to the controller 203, which in turn determines the connection status between the card and the card connector based upon the detection signal. As mentioned above, in accordance with embodiments of the present invention, when the connection status between the card and the card connector 100 changes, the electrical connection status between the switch member 201 and the contact terminal 103 will change accordingly. As a result, it is possible to determine the connection status between the card and the card connector, including any change thereof, based on the electrical connection status between the switch member 201 and the contact terminals 103 of the card connector 100.

FIGS. 3A and 3B show a stereo view (left) and a cross section view (right) of a configuration between the switch member 201 of the apparatus 200 and the contact terminal 103 of the card connector 100 in accordance with exemplary embodiments of the present invention. In this embodiment, the contact terminal 103 on the card connector is made of a curved, elastic conductive material which is common in the art, for example. The switch member 201 may be also made of an elastic conductive material such as solid metals. As shown, the switch member 201 of the apparatus 200 may be jointed to the housing member 102 of the card connector 100 adjacent to the contact terminal 103. Any suitable technical means may be applied to joint the switch member 201 and the contact terminal 103, no matter currently known or developed in the future. For example, the switch member 201 may be integrally formed with the housing member 103 in manufacturing. Alternatively, they can be jointed together by soldering, gluing, mechanical coupling, and the like. The scope of the present invention is not limited in this regard.

In operation, when the card is not connected to the card connector, the switch member 201 contacts with the contact terminals such that they are electrically connected. When the card is connected to the card connector, the contact terminal 103 is forced down. As a result, the contact terminal 103 which is made of elastic material will be deformed to disconnect from the switch member 201. Then when the card is removed from the card connector, the contact terminal 103 will rebound to restore the original position and connect with the switch member 201 again. In this way, the electrical connection status between the switch member 201 and the contact terminal 103, which changes as the card is connected and removed, may be used to determine the connection status between the card and the card connector.

It will be appreciated that the embodiment shown in FIG. 3 is merely exemplary and should not be constructed as the limit of the scope of the invention. For example, in alternative embodiments, the switch member 201 of the apparatus 200 may be positioned at a lower side with respect to the contact terminal 103 of the card connector 100, instead of the upper side as shown in FIG. 3. In these embodiments, when the card is not connected to the card connector 100, the switch member 201 is disconnected from the contact terminal 103; when the card is connected to the card connector 201, the contact terminal 103 is forced down by the card and deforms to connect with the switch member 201.

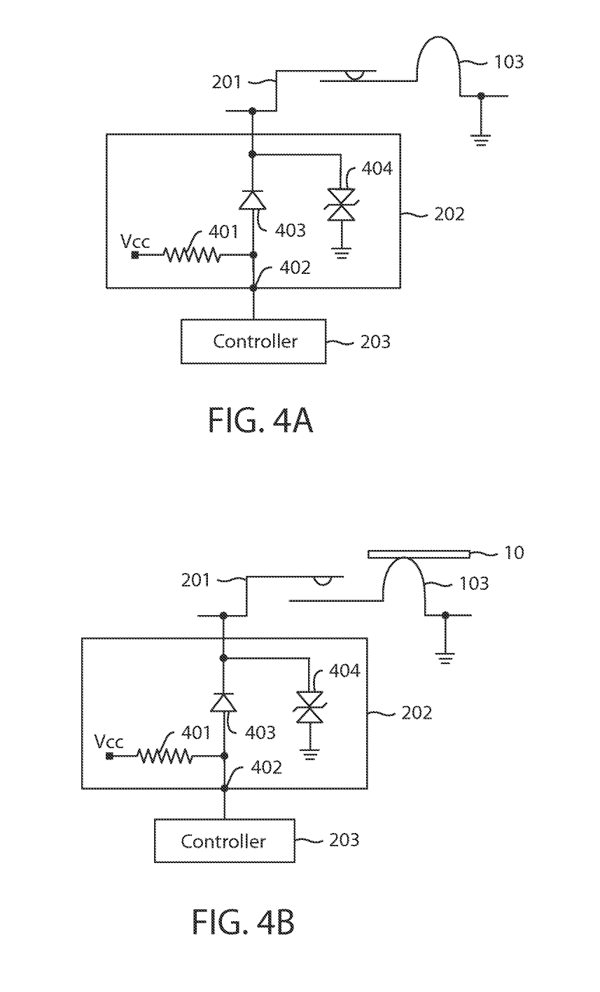

In accordance with embodiments of the present invention, the detection circuit 202 is operable to detect the electrical connection status between the switch member 201 and the contact terminal 103 and any change thereof. To this end, the detection circuit 202 comprises a status detection block operable to detect the electrical connection status between the switch member and the contact terminal of the card connector, where such electrical connection status changes responsive to a change in the connection status between the card and the card connector, as described above. The detection circuit 202 further comprises a detection signal generation block operable to generate a detection signal indicating the electrical connection status between the switch member and the contact terminal of the card connector for use in determining the connection status between the card and the card connector. Hereinafter, various possible implementations of the apparatus 200 and particularly the detection circuit 202 in accordance with embodiments of the present invention will be described with reference to FIGS. 4A-4B, 5A-5B, and 6A-6B.

FIGS. 4A and 4B show a block diagram of the detection circuit 202 in accordance with one exemplary embodiment of the present invention. In this embodiment, the detection circuit 202 is implemented as a voltage detection circuit, wherein voltage signals capable of indicating the electrical connection status between the switch member 201 and the contact terminal 103 are used as the detection signals. As shown in FIG. 4A, when the card is not connected to the card connector, the contact terminal 103 of the card connector 101 is in its original position and connected with the switch member 201. The contact terminal 103 is connected to the ground. In accordance with some embodiments, the ground (GND) terminal on the card connector may be selected to work in cooperation with the switch member 201. At this point, it is unnecessary to make any change to the structure of the card connector. Alternatively, any another contact terminal on the card connector, after being connected to the ground, may be used in cooperation with the switch member 201.

As shown, the detection circuit 202 comprises at least one resistor 401, which has large enough resistance value (e.g., 100 kΩ). One end of the resistor 401 is coupled to the switch member 201 and the other end is coupled to the power supply (Vcc) which may be 1.8V, for example. Additionally, the detection circuit 202 may comprise an optional diode 403 and an Electronic Statistic Discharge (ESD) Transient Voltage Suppressors (TVS) diode 404 which is connected to the ground. The diode 403 and the ESD TVS 404 are used to prevent a transient breakdown caused by the static electricity when the card is connected to the card connector. As such, the detection circuit 202 and the controller 203 may be protected from static electricity.

It would be appreciated that in the state shown in FIG. 4A where the detection circuit 202 is grounded via the switch member 201 and contact terminal 103, the voltage at the output terminal 402 of the detection circuit 202 is low. When a card 10 is connected to the card connector, the contact terminal 103 is forced down and disconnects from the switch member 201 (as shown in FIG. 4B). The voltage at the output terminal 402 of the detection circuit 202 will increase due to the pull-up effect of the resistor 401. On the contrary, when the card is removed from the connector, the contact terminal 103 and the switch member 201 will electrically connect with each other once again, causing the signal voltage at the output terminal 402 to decrease. Accordingly, the controller 203 is operable to determine that the card is connected to the card connector responsive to a voltage increase of the detection signal, and to determine that the card is removed from the card connector responsive to a voltage decrease of the detection signal.

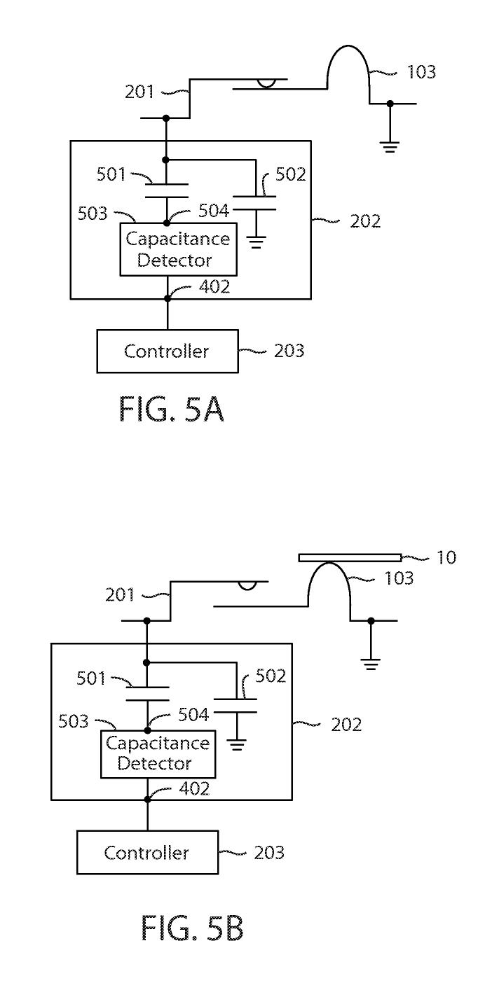

It is noted that the voltage detection circuit as shown in FIGS. 4A and 4B is just an example. In accordance with other embodiments of the present invention, the connection status between the card and the card connector may be detected based on the change of other electrical features caused by the change of electrical connection status between the switch member 201 and the contact terminal 103. FIGS. 5A and 5B show another example.

In the embodiment shown in FIGS. 5A and 5B, the detection circuit 202 is implemented as a capacitance detection circuit. As shown, the detection circuit 202 comprises a first capacitor 501 and a second capacitor 502. One end of the first capacitor 501 is coupled to the switch member 201 and the other end is coupled to the capacitance detector 503 which will be detailed below. One end of the second capacitor 502 is coupled to the switch member 201 and the other end is grounded. In some embodiments, the difference between the capacitances of the first and second capacitors 501 and 502 may be relatively large in order to meet certain engineering requirements. Only as an example, the capacitances of the first and second capacitors 501 and 502 may be set to be 4.7 pF and 47 pF, respectively. The detection circuit 202 also comprises a capacitance detector 503 which is operable to detect a capacitance at the terminal 504. The capacitance detector 503 is also operable to generate detection signals based on the detected capacitance and to output the generated detection signals to the controller 203 via the output terminal 402 of the detection circuit 202. The capacitance detector 503 may a capacitive touch or any other devices capable of detecting capacitance, no matter currently known or developed in the future. The scope of the invention is not limited in this regard.

In operation, in case that the card is not connected to the card connector, the switch member 201 is connected to the contact terminal 103, and the first capacitor 501 is therefore grounded (as shown in FIG. 5A). At this point, the capacitance of the second capacitor 502 may be detected at the terminal 504 of the capacitance detector 503. When the card is connected to the card connector, the contact terminal 103 is forced down and disconnects from the switch member 201 (as shown in FIG. 5B). As a result, the first capacitor 501 is connected in series with the second capacitor 502, and the capacitance detected at the terminal 504 of the capacitance detector 503 decreases accordingly. When the card is removed from the card connector, the contact terminal 103 rebounds and again connects with the switch member 201, which will cause the capacitance at the terminal 504 of the capacitance detector 503 to increase. The capacitance detection circuit 503 may generate the detection signal indicating the capacitance increase or decrease at the terminal 504, and output the detection signal to the controller 203 via the output terminal 402. In this way, the controller 203 may be operable to determine the connection status between the card and the connector based on the detection signal received from the detection circuit 202.

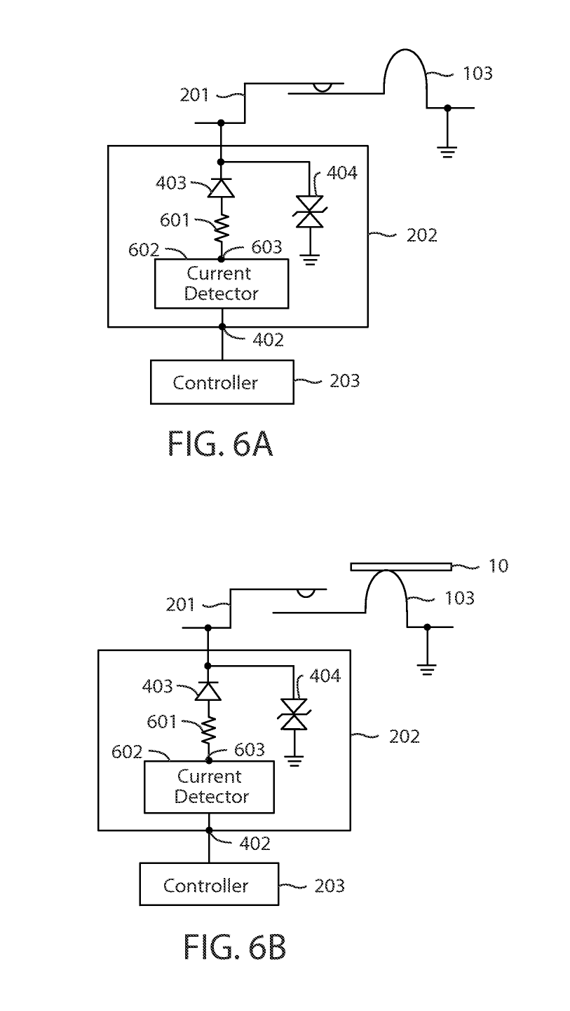

Next referring to FIGS. 6A and 6B, the apparatus 200 in accordance with yet another exemplary embodiment of the present invention is shown. In this embodiment, the detection circuit 202 is implemented as a current detection circuit. As shown, the detection circuit 202 comprises a resistor 601 and a current detector 602. One end of the resistor 601 is coupled to the switch member 201 and the other end is coupled to a current detector 602. The current detector 602 is operable to detect the current value at its terminal 603. The current detector 602 is also operable to generate the detection signal indicating an increase or decrease of the current value at the terminal 603 and to output the detection signal to the controller 203 via the output terminal 402. The current detector 603 may be a current sink or any other devices capable of detecting the current magnitude, no matter currently known or developed in the future. Further, the current detector 603 may involve a drive circuit (not shown in the figures). Optionally, the detection circuit 202 may comprise a diode 403 and an ESD TVS diode 404 for electrostatic protection.

In operation, in case that the card is not connected to the card connector, the switch member 201 and the contact terminal 103 connects with each other (as shown in FIG. 6A), and the current detector 602 may detect the current value at the terminal 603. When the card is connected to the card connector, the contact terminal 103 of the card connector is pressed down and disconnects from the switch member 201 (as shown in FIG. 6B). At this point, the current at the terminal 603 approaches to zero, i.e., there is a decrease of the current value. When the card is removed from the card connector, the contact terminal 103 and the switch member 201 reconnect such that the current value at the terminal 603 of the current detector 603 increases. The current detection circuit 602 is operable to generate the detection signal indicating the increase or decrease of current values at the terminal 603, and to output the detection signal to the controller 203 via the output terminal 402 of the detection circuit 202. In this way, the controller 203 may be operable to determine the connection status between the card and the card connector based on the detection signal received from the detection circuit 202.

Several exemplary embodiments of the apparatus 200 in accordance with embodiments of the present invention have been described. It will be appreciated that these embodiments are only for the purpose of illustration and should not be constructed as limits of the scope of the invention. In accordance with embodiments of the present invention, the electrical connection status between the switch member 201 and the contact terminal 103 may change as the connection status between the card and the car connector changes. Any circuits capable of detecting such change may function as the detection circuit 202 and fall within the scope of the present invention.

Specifically, it will be appreciated that the positional relationship between the switch member 201 and the contact terminal 103 as described above is only exemplary and should not be constructed as a limit of the scope of the present invention. In alternative embodiments, the switch member 201 and the contact terminal 103 may be disconnected in case that the card is not connected to the card connector while connected when the card is connected (by arranging the switch member 201 underneath the contact terminal 103, for example). At this point, it is just necessary to change the operation logic of the controller 203 to allow the proper operation of the apparatus 200. Considering the embodiment as shown in FIGS. 4A and 4B as an example, in this event, the controller 203 may be modified to determine that the card is connected responsive to a voltage decrease of the detection signal and determine that the card is removed responsive to a voltage increase of the detection signal. Likewise, the embodiments as shown in FIGS. 5A-5B and 6A-6B may be modified in a similar manner.

Next, an auxiliary switch member for facilitating hot swap of the card in accordance with optional embodiments of the present invention will be described. It should be understood that during the hot swap of a card, it is desired to detect the card removal as early as possible in order to protect relevant data and information timely and effectively. Therefore, in accordance with some optional embodiments of the present invention, the apparatus 200 may have an auxiliary switch member.

An example, in the embodiment of FIGS. 4A and 4B, when the card is connected to the card connector, the contact terminal 103 is forced down and disconnects from the switch member 201; when the card is removed from the card connector, the contact terminal 103 moves upwards and reconnect with the switch member 201. In this event, as will be appreciated, it will take a certain period of time for the contact terminal 103 to rebound to the original position to connect with the switch component 201. Therefore, there is a delay of time between the card removal and the detection of such removal by the detection circuit 202.

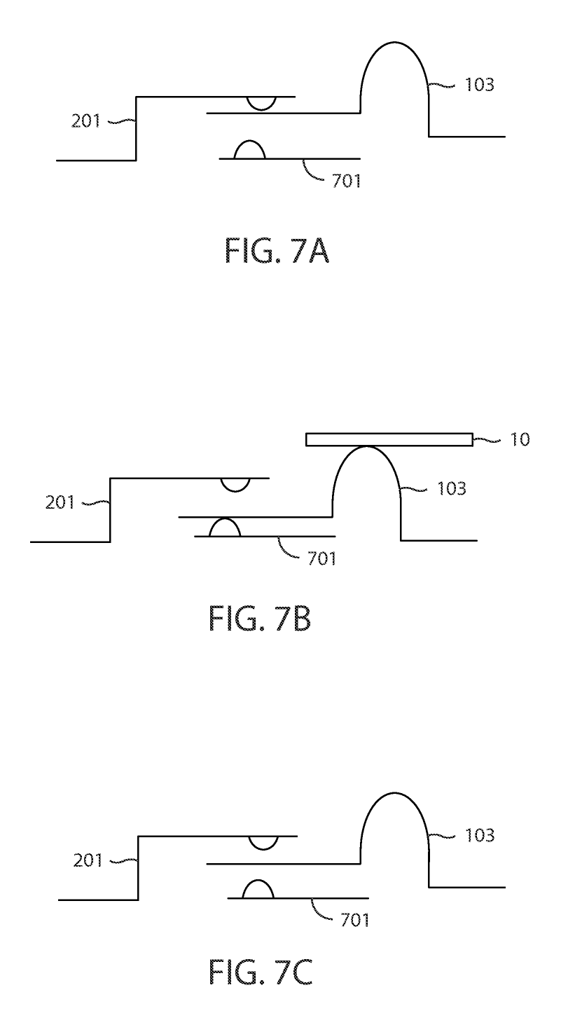

In some optional embodiments of the present invention, this problem is addressed by use of an auxiliary switch member. As shown in FIGS. 7A-7C, in such embodiments, the apparatus 201 may comprise an optional auxiliary switch member 701 which may be made of elastic, conductive material, for example. In this example, in case that the card is not connected to the card connector, the contact terminal 103 of the card connector 100 is connected with the switch member 201 and disconnected from the auxiliary switch member 701 (as shown in FIG. 7A). When the card is connected to the card connector 100, the contact terminal 103 is pressed down. As a result, the contact member 103 disconnects from the switch member 201 and connects to the auxiliary switch member 701 (as shown in FIG. 7B). Then, when the card is removed from the card connector 100, the contact terminal 103 will immediately disconnect from the auxiliary switch member 701. Accordingly, the detection circuit 202 is operable to detect the disconnection of the contact terminal 103 from the auxiliary switch member 701 and determine that the card has been removed accordingly, even if the contact terminal 103 has not connected to the switch member 201 yet (as shown in FIG. 7C). As such, the removal of the card may be detected earlier to provide a pre-warning mechanism for hot swap.

In order to support the auxiliary switch member, the detection circuit 202 may comprise an auxiliary status detection block operable to detect an electrical connection status between the auxiliary switch member and the contact terminal, wherein the auxiliary switch member is operable to disconnect from the contact terminal responsive to the removal of the card and prior to the connection of the switch member to the contact terminal, as described above. The detection circuit 202 may further comprise an auxiliary detection signal generation block operable to generate an auxiliary detection signal indicating the disconnection of the auxiliary switch member from the contact terminal. The auxiliary detection signal may be used by the controller 203 to determine the card removal from the card connector.

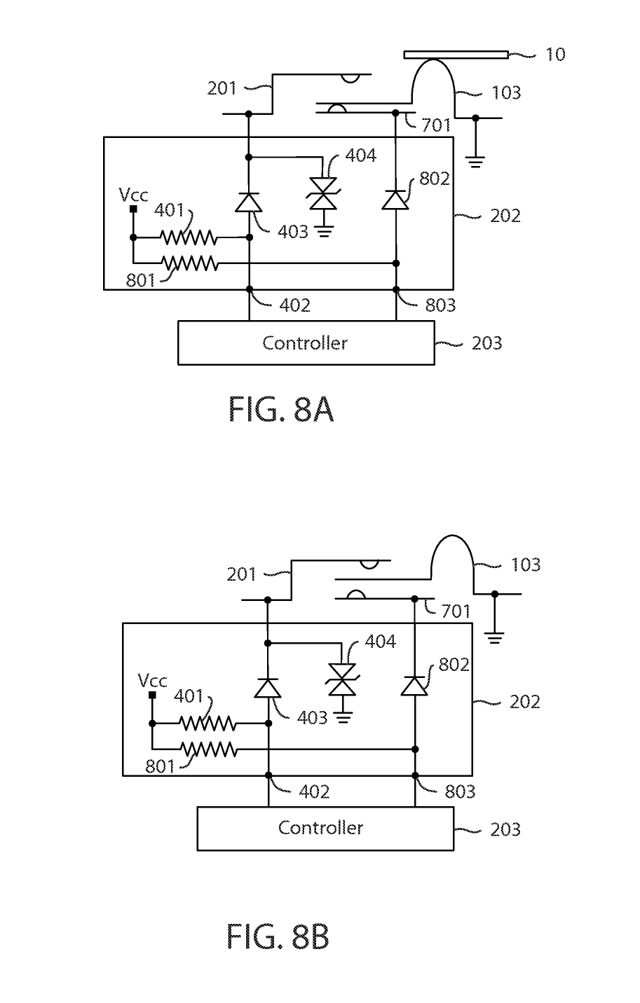

FIGS. 8A and 8B illustrate an exemplary detection circuit 202 enabling the auxiliary switch member 701. The detection circuit 202 shown in FIGS. 8A and 8B are obtained by modifying the arrangements in FIGS. 4A and 4B. Specifically, compared with the arrangement as shown in FIGS. 4A and 4B, the apparatus 202 in FIGS. 8A and 8B further comprises an auxiliary resistor 801, one end of which is coupled to the auxiliary switch member 701 with the other end coupled to the power supply (Vcc). Optionally, the detection circuit 202 may comprise an auxiliary diode 802 for electrostatic protection.

In operation, in case that the card is not connected with the card connector, the contact terminal 103 on the card connector 100 is disconnected from the switch member 201 and connected to the auxiliary switch member 701 (as shown in FIG. 8A). At this point, the voltage of the detection signal at the output terminal 402 is high, while the voltage of the auxiliary detection signal at the auxiliary output terminal 803 is low. When the card is removed, the contact terminal 103 will rebound upwards. In the state shown in FIG. 8B, the contact terminal 103 has not connected to the switch member 201 yet, and therefore the voltage of the detection signal at the output terminal 402 is still high. In the meantime, since the contact terminal 103 has disconnected from the auxiliary switch member 701, the voltage of the auxiliary detection signal at the auxiliary output terminal 803 will be pulled up by the resistor 801. Accordingly, the controller 203 may timely detect the card removal based on the voltage increase of the auxiliary detection signal. In this manner, the hot swap may be better supported.

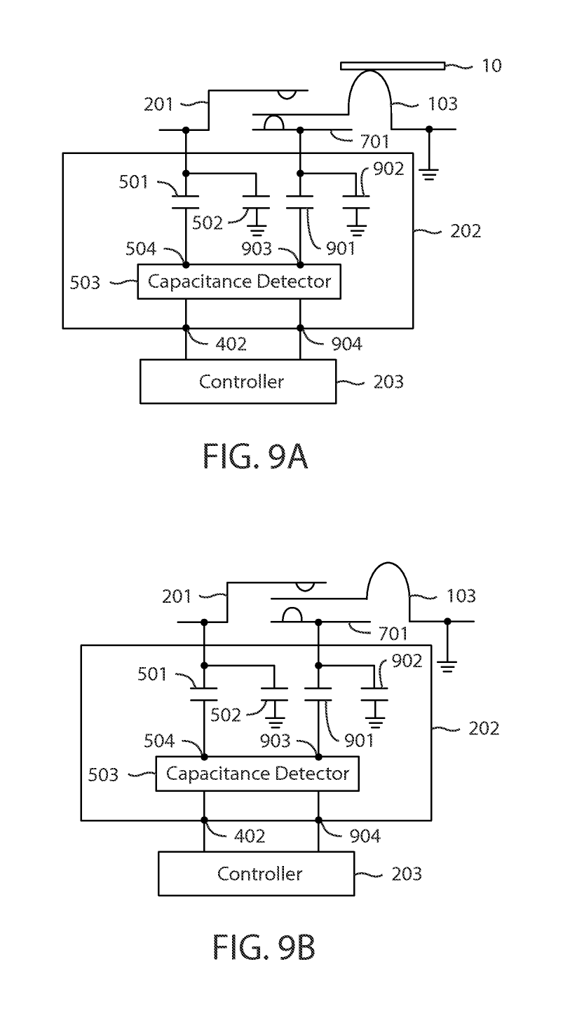

FIGS. 9A and 9B illustrate another exemplary apparatus 200 supporting the auxiliary switch member 701. The detection circuit 202 as shown in FIGS. 9A and 9B are obtained by modifying the arrangement in FIGS. 5A and 5B. Compared with the embodiments in FIGS. 5A and 5B, the detection circuit 202 further comprises a first auxiliary capacitor 901 and a second auxiliary capacitor 902. One end of the first auxiliary capacitor 901 is coupled to the auxiliary switch member 701, and the other end is coupled to an auxiliary terminal 903 of the capacity detector 503. One end of the second capacitor 902 is coupled to the auxiliary switch member 701, while the other end is grounded. In some optional embodiments, the difference between the capacitances of the first and second auxiliary capacitors 901 and 902 may but not necessarily be relatively large.

In this embodiment, when the card is connected to the card connector, the contact terminal 103 of the card connector 100 is disconnected from the switch member 201 and connected with the auxiliary switch member 701 (as shown in FIG. 9A). At this point, the first capacitor 501 is connected in series with the second capacitor 502, and the capacitance at the terminal 504 of the capacitance detector 503 is therefore relatively low. In the meantime, since the first auxiliary capacitor 901 is grounded, the capacitance detected at the auxiliary terminal 903 is relatively high. When the card is removed from the card connector 100, the contact terminal 103 rebounds. In the state as shown in FIG. 9B, the contact terminal 103 has not yet connected to the switch member 201 and the capacitance at the terminal 504 is still low. The contact terminal 103, however, has already disconnected from the auxiliary switch member 701, and the first and second auxiliary capacitors 901 and 902 are connected in series. As a result, the capacitance detected at the auxiliary terminal 903 decreases. Accordingly, the capacitance detector 503 in this embodiment is operable to generate an auxiliary detection signal indicating the capacitance increase or decrease at the auxiliary terminal 903 and to output the auxiliary detection signal to the controller 203 via the auxiliary output terminal 904. The controller 203 in turn may timely detect the card removal based on the auxiliary detection signal.

It should be note that the auxiliary switch member 701 described above is optional. For example, by adopting appropriate materials and/or properly arranging the switch member 201 and the contact terminal 103, it is possible to reduce the latency from the removal of card to the connection of the switch member 201 and the contact terminal 103. In this event, the auxiliary switch member 701 may be omitted. For another example, if the switch member 201 and the contact terminal 103 are connected with each other when the card is connected to the card connector 100, then the detection circuit 202 is able to detect the disconnection of the switch member 201 from the contact terminal 103 immediately after the card is removed without any delay. In this event, the controller 203 can timely determine the removal of card and the auxiliary switch member 701 may be omitted as well.

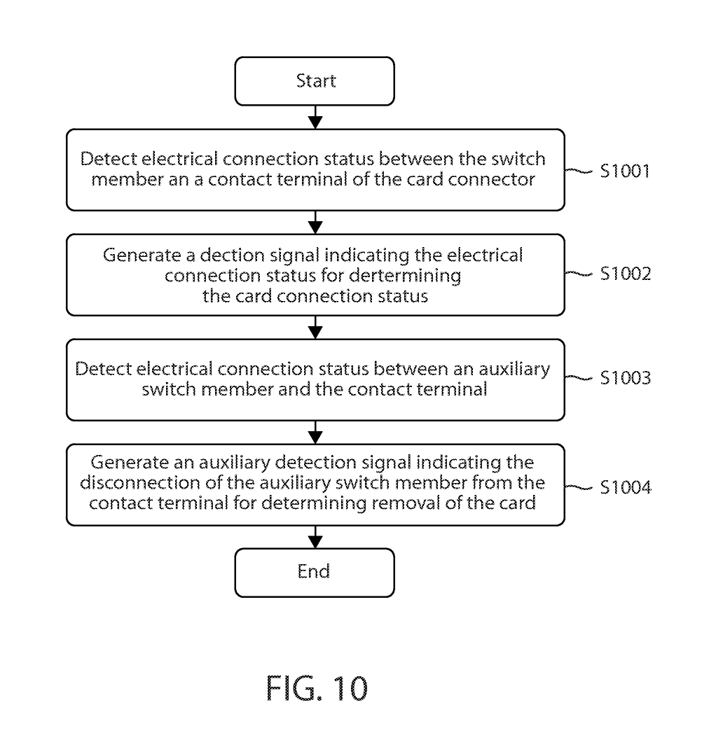

Reference is now made to FIG. 10, where a flowchart of a method in accordance with the embodiments of the present invention is shown. It would be appreciated that the method may be carried out by the apparatus 200 as described above. After the method starts, at step S1001, the electric connection status between the switch member and the contact terminal of the card connector is detected, wherein the electrical connection status changes responsive to any change of the connection status between the card and the card connector. Next, a detection signal is generated at step S1002, the detection signal indicating the electrical connection status between the switch member and the contact terminal. In accordance with embodiments of the present invention, the detection signal may be generated based on the voltage, current, and/or capacitance corresponding to the electrical connection status between the switch member and the contact terminal The detection signal may be used to determine the connection status between the card and the card connector.

In some optional embodiments, the switch member may be operable to connect to the contact terminal responsive to a removal of the card from the card connector. In these embodiments, at optional step S1003, the electrical connection status between the auxiliary switch member and the contact terminal may be detected, wherein the auxiliary switch member is operable to disconnect from the contact terminal responsive to the removal of the card from the card connector and prior to the connection of the switch member to the contact terminal Accordingly, an auxiliary detection signal indicating the disconnection of the auxiliary switch member from the contact terminal may be generated at step S1004 for use in determining the removal of card.

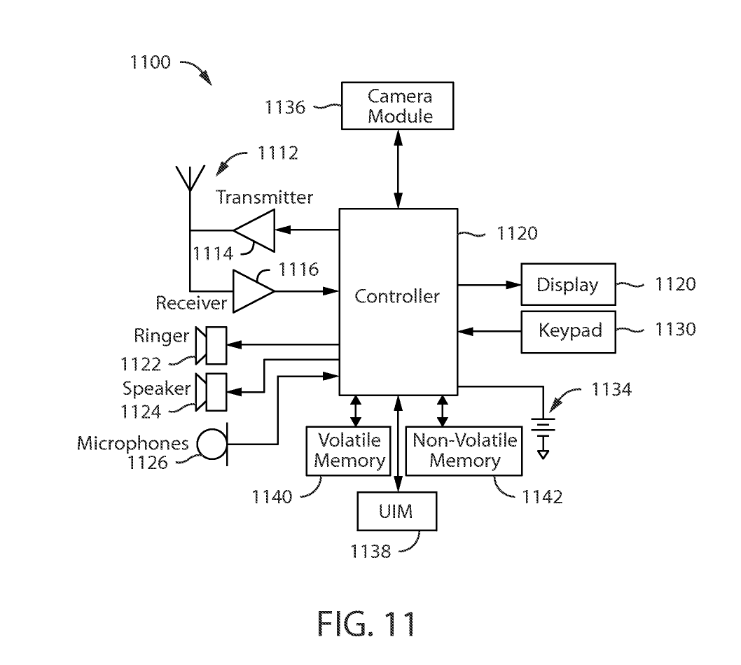

FIG. 11 shows a block diagram of a user terminal in which exemplary embodiments of the present invention may be implemented. In this example, the user terminal 1100 is shown as a mobile device having radio communication capabilities. However, it should be understood that it is merely exemplary and non-limiting. Other types of user terminals may also easily adopt the embodiments of the present invention, such as a portable digital assistant (PDA), a pager, a mobile computer, a mobile TV, a game apparatus, a laptop, a camera, a video camera, a GPS device, and other types of voice and textual communication system. A fixed-type user terminal may likewise easily use the embodiments of the present invention.

The user terminal 1100 includes an antenna(s) 1112 in operable communication with a transmitter 1114 and a receiver 1116. The user terminal 1100 further includes at least one processor or controller 1120. It should be understood that the controller 1120 includes circuitry required for implementing the function of the user terminal 1100. For example, the controller 1120 may be comprised of a digital signal processor, a microprocessor, and various analog to digital converters, digital to analog converters, and other support circuits. Control and information processing functions of the user terminal 1100 are allocated between these devices in accordance with their respective capabilities.

The user terminal 1100 also comprises a user interface, which may include a ringer 1122, a speaker 1124, a microphone 1126, a display 1128, and a keypad 1130 as a user input device, all of which are coupled to the controller 1120. The user terminal 1100 may further comprise a camera module 1136 for capturing still and/or dynamic images.

The user terminal 1100 further comprises a battery 1134, such as a vibrating battery pack for powering various circuits that are required to operate the user terminal 1100, as well as optionally providing mechanical vibration as a detectable output. The user terminal 1100 may further include a universal identity module (UIM) 1138. The UIM 1138 is typically a memory device having a processor built in. The UIM 1138 may include, for example, a subscriber identity module (SIM), a universal integrated circuit card (UICC), a universal subscriber identity module (USIM), a removable user identity module (R-UIM), etc. The UIM 1138 may comprise a card connection detecting apparatus in accordance with the embodiments of the present invention.

The user terminal 1100 further comprises a memory. For example, the user terminal 1100 may include volatile memory 1140, such as volatile Random Access Memory (RAM) including a cache area for the temporary storage of data. The user terminal 1100 may also include other non-volatile memory 1142, which can be embedded and/or may be removable. The non-volatile memory 1142 can additionally or alternatively comprise an EEPROM, flash memory or the like. The memories can store any of a number of pieces of information, program, and data, used by the user terminal 1100 to implement the functions of the user terminal 1100.

It should be understood that the structural block diagram in FIG. 11 is shown only for illustration purpose, and is not intended to limit the scope of the present invention. In some cases, some devices may be added or reduced as required.

The several exemplary embodiments of the present invention have been described above just for the purpose of illustration. Embodiments of the present invention can be implemented with software, hardware or the combination thereof. The hardware part can be implemented by a special logic; the software part can be stored in a memory and executed by a proper instruction execution system such as a microprocessor or a design-specific hardware. The normally skilled in the art may understand that the above method and system may be implemented with a computer-executable instruction and/or in a processor controlled code, for example, such code is provided on a bearer medium such as a magnetic disk, CD, or DVD-ROM, or a programmable memory such as a read-only memory (firmware) or a data bearer such as an optical or electronic signal bearer. The system of the present invention may be implemented by hardware circuitry of a programmable hardware device such as a very large scale integrated circuit or gate array, a semiconductor such as logical chip or transistor, or a field-programmable gate array, or a programmable logical device, or implemented by software executed by various kinds of processors, or implemented by combination of the above hardware circuitry and software.

It should be noted that although a plurality of modules or sub-modules of the system have been mentioned in the above detailed depiction, such partitioning is merely non-compulsory. In actuality, in accordance with the embodiments of the present invention, the features and functions of the above described two or more modules may be embodied in one means. In turn, the features and functions of the above described one means may be further embodied in more modules. Besides, although operations of the present methods are described in a particular order in the drawings, it does not require or imply that these operations must be performed in accordance with this particular order, or a desired outcome can only be achieved by performing all shown operations. On the contrary, the execution order for the steps as depicted in the flowcharts may be varied. Additionally or alternatively, some steps may be omitted, a plurality of steps may be merged into one step, or a step may be divided into a plurality of steps for execution.

Although the present invention has been depicted with reference to a plurality of embodiments, it should be understood that the present invention is not limited to the disclosed embodiments. On the contrary, the present invention intends to cover various modifications and equivalent arrangements included in the spirit and scope of the appended claims. The scope of the appended claims meets the broadest explanations and covers all such modifications and equivalent structures and functions.

What is claimed is:

1. An apparatus for detecting a card connection status, comprising:
a switch member configured to change an electric connection status with a contact terminal of a card connector responsive to a change of a connection status between a card and the card connector;
a detection circuit configured to generate a detection signal indicating the electric connection status between the switch member and the contact terminal; and
a controller configured to determine the connection status between the card and the card connector based on the detection signal from the detection circuit.

2. The apparatus in accordance with claim 1, wherein the switch member is configured to connect to the contact terminal responsive to a removal of the card from the card connector.

3. The apparatus in accordance with claim 1, wherein the switch member is configured to disconnect from the contact terminal responsive to an insertion of the card to the card connector.

4. The apparatus in accordance with claim 2, further comprising:
an auxiliary switch member configured to disconnect from the contact terminal responsive to the removal of the card from the card connector and prior to the connection of the switch member to the contact terminal.

5. The apparatus in accordance with claim 4, wherein the detection circuit is further configured to generate an auxiliary detection signal indicating the disconnection of the auxiliary switch member from the contact terminal,
and wherein the controller is further configured to determine the removal of the card from the card connector based on the auxiliary detection signal from the detection circuit.

6. A user terminal comprising the apparatus according to claim 5.

7. The apparatus in accordance with claim 1, wherein the switch member is a conductive spring and jointed to a housing member of the card connector adjacent to the contact terminal.

8. The apparatus in accordance with claim 1, wherein the contact terminal is a ground terminal of the card connector.

9. A user terminal comprising the apparatus according to claim 1.

10. A card connector, comprising:
a housing member;
at least one contact terminal; and
a switch member configured to change an electric connection status with one of the at least one contact terminal responsive to a change of a connection status between a card and the card connector.

11. The card connector in accordance with claim 10, wherein the switch member is configured to disconnect to the at least one contact terminal responsive to a insertion of the card to the card connector.

12. The card connector in accordance with claim 10, wherein the switch member is configured to connect to the one of the at least one contact terminal responsive to a removal of the card from the card connector,

13. The card connector in accordance with claim 12, further comprising:
an auxiliary switch member operable to disconnect from the one of the least one contact terminal responsive to the removal of the card from the card connector and prior to the connection of the switch member to the least one contact terminal.

14. The card connector in accordance with claim 10, wherein the switch member is a conductive spring and jointed to the housing member adjacent to the one of the at least one contact terminal.

15. The card connector in accordance with claim 10, wherein the at least one contact terminal is a ground terminal of the card connector.

16. A user terminal comprising the card connector of claim 10.

17. A method for detecting a card connection status, comprising:
detecting an electrical connection status between a switch member and a contact terminal of a card connector, the electrical connection status changing responsive to a change of a connection status between a card and the card connector; and
generating a detection signal indicating the electrical connection status between the switch member and the contact terminal for determining the connection status between the card and the card connector.

18. The method in accordance with claim 17, wherein the switch member is operable to connect to the contact terminal responsive to a removal of the card from the card connector, the method further comprising:
detecting an electrical connection status between an auxiliary switch member and the contact terminal, the auxiliary switch member being operable to disconnect from the contact terminal responsive to the removal of the card from the card connector and prior to the connection of the switch member to the contact terminal.

19. The method in accordance with claim 18, further comprising:
generating an auxiliary detection signal indicating the disconnection of the auxiliary switch member from the contact terminal for determining the removal of the card from the card connector.
